(19) United States
(12) Patent Application Publication
(10) Pub. No.: US 2025/0232954 A1
(43) Pub. Date: Jul. 17, 2025

(54) PLASMA PROCESSING APPARATUS AND POWER SUPPLY SYSTEM

(71) Applicant: Tokyo Electron Limited, Tokyo (JP)

(72) Inventors: Mitsuhiro IWANO, Miyagi (JP); Motoki NORO, Miyagi (JP)

(73) Assignee: Tokyo Electron Limited, Tokyo (JP)

(21) Appl. No.: 19/093,832

(22) Filed: Mar. 28, 2025

Related U.S. Application Data
(63) Continuation of application No. PCT/JP2023/032799, filed on Sep. 8, 2023.

(30) Foreign Application Priority Data
Sep. 29, 2022 (JP) 2022-156980

(51) Int. Cl. H01J 37/32

(52) U.S. Cl. CPC H01J 37/32165; H01J 37/32146; H01J 37/32568; H01J 37/32935; H01J 2237/3347

(57) ABSTRACT

The purpose of the technique is to improve controllability of plasma formed on a substrate. A plasma processing apparatus includes a chamber; a substrate support that is disposed in the chamber and includes a lower electrode; an upper electrode that is disposed above the substrate support; a first RF power supply configured to supply a first RF signal having a first RF frequency to the upper electrode or the lower electrode; a second RF power supply configured to supply a second RF signal having a second RF frequency to the lower electrode; and a third RF power supply configured to supply a third RF signal having a third RF frequency to the lower electrode. Three RF power supplies supply RF signals having respective power levels in four periods in each cycle.

### CROSS-REFERENCE TO RELATED APPLICATIONS

This application is a bypass continuation application of international application No. PCT/JP2023/032799 having an international filing date of Sep. 8, 2023 and designating the United States, the international application being based upon and claiming the benefit of priority from Japanese Patent Application No. 2022-156980, filed on Sep. 29, 2022, the entire contents of each are incorporated herein by reference.

### BACKGROUND

### Field

An exemplary embodiment of the present disclosure relates to a plasma processing apparatus and a power supply system.

### Description of Related Art

The specification of US2017/0125260A discloses a technique for controlling ions in plasma in an etching process.

### SUMMARY

A plasma processing apparatus in one exemplary aspect of the present disclosure includes a chamber; a substrate support that is disposed in the chamber and includes a lower electrode; an upper electrode that is disposed above the substrate support; a first radio frequency (RF) power supply configured to supply a first RF signal having a first RF frequency to the upper electrode or the lower electrode, in which the first RF signal has a first power level during a first period in each cycle, has a second power level during a second period after the first period in each cycle, has a third power level during a third period after the second period in each cycle, and has a fourth power level during a fourth period after the third period in each cycle, the second power level is less than the first power level, and the fourth power level has a zero power level; a second RF power supply configured to supply a second RF signal having a second RF frequency to the lower electrode, in which the second RF signal has a fifth power level during the first period in each cycle, has a sixth power level during the second period in each cycle, has a seventh power level during the third period in each cycle, and has an eighth power level during the fourth period in each cycle, and each of the fifth power level and the eighth power level have a zero power level; and a third RF power supply configured to supply a third RF signal having a third RF frequency to the lower electrode, in which the third RF signal has a ninth power level during the first period in each cycle, has a tenth power level during the second period in each cycle, has an eleventh power level during the third period in each cycle, and has a twelfth power level during the fourth period in each cycle, and each of the ninth power level, the tenth power level and the eleventh power level have a zero power level.

### BRIEF DESCRIPTION OF DRAWINGS

FIG. 1 is a diagram for illustrating a configuration example of a plasma processing system.

FIG. 2 is a diagram for illustrating a configuration example of a capacitively coupled plasma processing apparatus.

FIG. 3 is a diagram for illustrating a configuration of a plasma processing apparatus in a first exemplary aspect.

FIG. 4 is a diagram illustrating an example of supply of a first RF signal, a second RF signal, and a third RF signal.

FIG. 5 is a descriptive diagram for illustrating an example of a relationship between three types of RF signals and ion energy (Ei) and ion flux (Flux) of ions in plasma on a substrate.

FIG. 6 is a descriptive diagram for illustrating an example of a behavior of ions in plasma in a first period, a second period, a third period, and a fourth period.

FIG. 7 is a diagram for illustrating an example of supply of the first RF signal, the second RF signal, and the third RF signal.

FIG. 8 is a diagram illustrating an example of supply of the first RF signal, the second RF signal, and the third RF signal.

FIG. 9 is a descriptive diagram for illustrating an example of fluctuations in ion energy (Ei) and ion flux (Flux) during the first period, the second period, the third period, and the fourth period.

FIG. 10 is a diagram illustrating an example of supply of the first RF signal, the second RF signal, and the third RF signal.

FIG. 11 is a diagram for illustrating a configuration of a plasma processing apparatus that uses a voltage pulse signal in the first exemplary aspect.

FIG. 12 is a diagram illustrating an example of the supply of the first RF signal and the second RF signal and the application of the voltage pulse signal.

FIG. 13 is a diagram for illustrating a configuration of a plasma processing apparatus in a second exemplary aspect.

FIG. 14 is a diagram illustrating an example of supply of the first RF signal and the second RF signal.

FIG. 15 is a descriptive diagram for illustrating an example of a relationship between two types of RF signals and ion energy (Ei) and ion flux (Flux) of ions in plasma on the substrate.

FIG. 16 is a diagram for illustrating a configuration of the plasma processing apparatus that uses the voltage pulse signal in the second exemplary aspect.

FIG. 17 is a diagram illustrating an example of the supply of the first RF signal and the application of the voltage pulse signal.

### DETAILED DESCRIPTION

Hereinafter, each embodiment of the present disclosure will be described.

In one exemplary embodiment, there is provided a plasma processing apparatus including: a chamber; a substrate support that is disposed in the chamber and includes a lower electrode; an upper electrode that is disposed above the substrate support; a first RF power supply configured to supply a first RF signal having a first RF frequency to the upper electrode or the lower electrode, in which the first RF signal has a first power level during a first period in each cycle, has a second power level during a second period after the first period in each cycle, has a third power level during a third period after the second period in each cycle, and has a fourth power level during a fourth period after the third period in each cycle, the second power level is less than the first power level, and the fourth power level has a zero power level; a second RF power supply configured to supply a second RF signal having a second RF frequency to the lower electrode, in which the second RF signal has a fifth power level during the first period in each cycle, has a sixth power level during the second period in each cycle, has a seventh power level during the third period in each cycle, and has an eighth power level during the fourth period in each cycle, and each of the fifth power level and the eighth power level have a zero power level; and a third RF power supply configured to supply a third RF signal having a third RF frequency to the lower electrode, in which the third RF signal has a ninth power level during the first period in each cycle, has a tenth power level during the second period in each cycle, has an eleventh power level during the third period in each cycle, and has a twelfth power level during the fourth period in each cycle, and each of the ninth power level, the tenth power level and the eleventh power level have a zero power level.

In one exemplary embodiment, the third power level has a zero power level, and the seventh power level is greater than the sixth power level.

In one exemplary embodiment, the third power level is equal to the second power level, and the seventh power level is greater than the sixth power level.

In one exemplary embodiment, the third power level is greater than the second power level, and the seventh power level has a zero power level.

In one exemplary embodiment, the first RF frequency is larger than the second RF frequency, and the second RF frequency is larger than the third RF frequency.

In one exemplary embodiment, the third RF frequency is in a range of 300 kHz to 600 KHz.

In one exemplary embodiment, there is provided a plasma processing apparatus including: a chamber; a substrate support that is disposed in the chamber and includes a lower electrode; an upper electrode that is disposed above the substrate support; a first RF power supply configured to supply a first RF signal having a first RF frequency to the upper electrode or the lower electrode, in which the first RF signal has a first power level during a first period in each cycle, has a second power level during a second period after the first period in each cycle, has a third power level during a third period after the second period in each cycle, and has a fourth power level during a fourth period after the third period in each cycle, the second power level is less than the first power level, and the fourth power level has a zero power level; a second RF power supply configured to supply a second RF signal having a second RF frequency to the lower electrode, in which the second RF signal has a fifth power level during the first period in each cycle, has a sixth power level during the second period in each cycle, has a seventh power level during the third period in each cycle, and has an eighth power level during the fourth period in each cycle, and each of the fifth power level and the eighth power level have a zero power level; and a voltage pulse generator configured to apply a voltage pulse signal to the lower electrode, in which the voltage pulse signal has a first voltage level during the first period, the second period, and the third period in each cycle, and has a sequence of voltage pulses having a second voltage level during the fourth period in each cycle, and an absolute value of the second voltage level is larger than an absolute value of the first voltage level.

In one exemplary embodiment, the third power level has a zero power level, and the seventh power level is greater than the sixth power level.

In one exemplary embodiment, the third power level is equal to the second power level, and the seventh power level is greater than the sixth power level.

In one exemplary embodiment, the third power level is greater than the second power level, and the seventh power level has a zero power level.

In one exemplary embodiment, the second voltage level has a negative polarity.

In one exemplary embodiment, the first voltage level has a zero voltage level.

In one exemplary embodiment, the sequence of the voltage pulses has a pulse frequency in a range of 300 kHz to 600 KHz.

In one exemplary embodiment, there is provided a plasma processing apparatus including: a chamber; a substrate support that is disposed in the chamber and includes a lower electrode; an upper electrode that is disposed above the substrate support; a first RF power supply configured to supply a first RF signal having a first RF frequency to the upper electrode or the lower electrode, in which the first RF frequency has a MHz band, the first RF signal has a first power level during a first period in each cycle, has a second power level during a second period after the first period in each cycle, has a third power level during a third period after the second period in each cycle, and has a fourth power level during a fourth period after the third period in each cycle, the second power level is less than the first power level, the third power level is greater than the second power level, and the fourth power level has a zero power level; and a second RF power supply configured to supply a second RF signal having a second RF frequency to the lower electrode, in which the second RF frequency has a kHz band, the second RF signal has a fifth power level during the first period in each cycle, has a sixth power level during the second period in each cycle, has a seventh power level during the third period in each cycle, and has an eighth power level during the fourth period in each cycle, each of the fifth power level and the seventh power level have a zero power level, and the eighth power level is equal to or greater than the sixth power level.

In one exemplary embodiment, the second RF signal has an RF frequency in a range of 300 kHz to 600 KHz.

In one exemplary embodiment, there is provided a plasma processing apparatus including: a chamber; a substrate support that is disposed in the chamber and includes a lower electrode; an upper electrode that is disposed above the substrate support; an RF power supply configured to supply an RF signal to the upper electrode or the lower electrode, in which the RF signal has a first power level during a first period in each cycle, has a second power level during a second period after the first period in each cycle, has a third power level during a third period after the second period in each cycle, and has a fourth power level during a fourth period after the third period in each cycle, the second power level is less than the first power level, the third power level is greater than the second power level, and the fourth power level has a zero power level; and a voltage pulse generator configured to apply a voltage pulse signal to the lower electrode, in which the voltage pulse signal has a first voltage level during the first period and the third period in each cycle, has a sequence of voltage pulses having a second voltage level during the second period in each cycle, and has a sequence of voltage pulses having the second voltage level or a third voltage level during the fourth period in each cycle, an absolute value of the second voltage level is larger than an absolute value of the first voltage level, and an absolute value of the third voltage level is larger than the absolute value of the second voltage level.

In one exemplary embodiment, there is provided a power supply system for use in a plasma processing apparatus, including: a first RF generator configured to generate a first RF signal having a first RF frequency, in which the first RF signal has a first power level during a first period in each cycle, has a second power level during a second period after the first period in each cycle, has a third power level during a third period after the second period in each cycle, and has a fourth power level during a fourth period after the third period in each cycle, the second power level is less than the first power level, and the fourth power level has a zero power level;
a second RF generator configured to generate a second RF signal having a second RF frequency, in which the second RF signal has a fifth power level during the first period in each cycle, has a sixth power level during the second period in each cycle, has a seventh power level during the third period in each cycle, and has an eighth power level during the fourth period in each cycle, and each of the fifth power level and the eighth power level have a zero power level; and a third RF generator configured to generate a third RF signal having a third RF frequency, in which the third RF signal has a ninth power level during the first period in each cycle, has a tenth power level during the second period in each cycle, has an eleventh power level during the third period in each cycle, and has a twelfth power level during the fourth period in each cycle, and each of the ninth power level, the tenth power level and the eleventh power level have a zero power level.

In one exemplary embodiment, there is provided a power supply system for use in a plasma processing apparatus, including: a first RF generator configured to generate a first RF signal having a first RF frequency, in which the first RF signal has a first power level during a first period in each cycle, has a second power level during a second period after the first period in each cycle, has a third power level during a third period after the second period in each cycle, and has a fourth power level during a fourth period after the third period in each cycle, the second power level is less than the first power level, and the fourth power level has a zero power level;
a second RF generator configured to generate a second RF signal having a second RF frequency, in which the second RF signal has a fifth power level during the first period in each cycle, has a sixth power level during the second period in each cycle, has a seventh power level during the third period in each cycle, and has an eighth power level during the fourth period in each cycle, and each of the fifth power level and the eighth power level have a zero power level; and a voltage pulse generator configured to generate a voltage pulse signal, in which the voltage pulse signal has a first voltage level during the first period, the second period, and the third period in each cycle, and has a sequence of voltage pulses having a second voltage level during the fourth period in each cycle, and an absolute value of the second voltage level is larger than an absolute value of the first voltage level.

In one exemplary embodiment, there is provided a power supply system for use in a plasma processing apparatus, including: a first RF generator configured to generate a first RF signal having a first RF frequency, in which the first RF frequency has a MHz band, the first RF signal has a first power level during a first period in each cycle, has a second power level during a second period after the first period in each cycle, has a third power level during a third period after the second period in each cycle, and has a fourth power level during a fourth period after the third period in each cycle, the second power level is less than the first power level, the third power level is greater than the second power level, and the fourth power level has a zero power level; and a second RF generator configured to generate a second RF signal having a second RF frequency, in which the second RF frequency has a kHz band, the second RF signal has a fifth power level during the first period in each cycle, has a sixth power level during the second period in each cycle, has a seventh power level during the third period in each cycle, and has an eighth power level during the fourth period in each cycle, each of the fifth power level and the seventh power level have a zero power level, and the eighth power level is equal to or greater than the sixth power level.

In one exemplary embodiment, there is provided a power supply system for use in a plasma processing apparatus, including: an RF generator configured to generate an RF signal, in which the RF signal has a first power level during a first period in each cycle, has a second power level during a second period after the first period in each cycle, has a third power level during a third period after the second period in each cycle, and has a fourth power level during a fourth period after the third period in each cycle, the second power level is less than the first power level, the third power level is greater than the second power level, and the fourth power level has a zero power level; and a voltage pulse generator configured to generate a voltage pulse signal, in which the voltage pulse signal has a first voltage level during the first period and the third period in each cycle, has a sequence of voltage pulses having a second voltage level during the second period in each cycle, and has a sequence of voltage pulses having the second voltage level or a third voltage level during the fourth period in each cycle, an absolute value of the second voltage level is larger than an absolute value of the first voltage level, and an absolute value of the third voltage level is larger than the absolute value of the second voltage level.

Hereinafter, each embodiment of the present disclosure will be described in detail with reference to the drawings. In each drawing, the same or similar elements will be given the same reference numerals, and repeated descriptions will be omitted. Unless otherwise specified, a positional relationship such as up, down, left, and right will be described based on a positional relationship illustrated in the drawings. A dimensional ratio in the drawings does not indicate an actual ratio, and the actual ratio is not limited to the ratio illustrated in the drawings.

### Example of Plasma Processing System

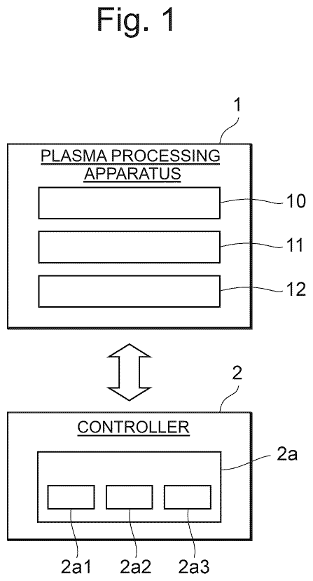

FIG. 1 is a diagram for illustrating a configuration example of a plasma processing system. In an embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber (also simply referred to as a “chamber”) 10, a substrate support 11, and a plasma generator 12. The plasma processing chamber 10 has a plasma processing space. In addition, the plasma processing chamber 10 has at least one gas supply port for supplying at least one processing gas to the plasma processing space and at least one gas exhaust port for exhausting the gas from the plasma processing space. The gas supply port is connected to a gas supply 20, described later, and the gas exhaust port is connected to an exhaust system 40, described later. The substrate support 11 is disposed in the plasma processing space and has a substrate support surface for supporting a substrate.

The plasma generator 12 is configured to form a plasma from at least one processing gas supplied into the plasma processing space. The plasma formed in the plasma processing space may be a capacitively coupled plasma (CCP), an inductively coupled plasma (ICP), an electron-cyclotron-resonance plasma (ECR plasma), a helicon wave plasma (HWP), a surface wave plasma (SWP), or the like. Further, various types of plasma generators including an alternating current (AC) plasma generator and a direct current (DC) plasma generator may be used. In an embodiment, an AC signal (AC power) used in the AC plasma generator has a frequency in the range of 100 kHz to 10 GHz. Therefore, the AC signal includes an RF signal and a microwave signal. In an embodiment, the RF signal has a frequency in the range of 100 kHz to 150 MHz.

The controller 2 processes a computer-executable instruction that causes the plasma processing apparatus 1 to execute various steps described in the present disclosure. The controller 2 may be configured to control each element of the plasma processing apparatus 1 such that the various steps described here are executed. In an embodiment, a part or the entirety of the controller 2 may be included in the plasma processing apparatus 1. The controller 2 may include a processor 2a1, a storage 2a2, and a communication interface 2a3. The controller 2 is realized by, for example, a computer 2a. The processor 2a1 may be configured to read out a program from the storage 2a2 and to execute the read-out program to perform various control operations. This program may be stored in the storage 2a2 in advance, or may be acquired through a medium when necessary. The acquired program is stored in the storage 2a2, is read out from the storage 2a2, and executed by the processor 2a1. The medium may be various storage media readable by the computer 2a or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 through a communication line such as a local area network (LAN).

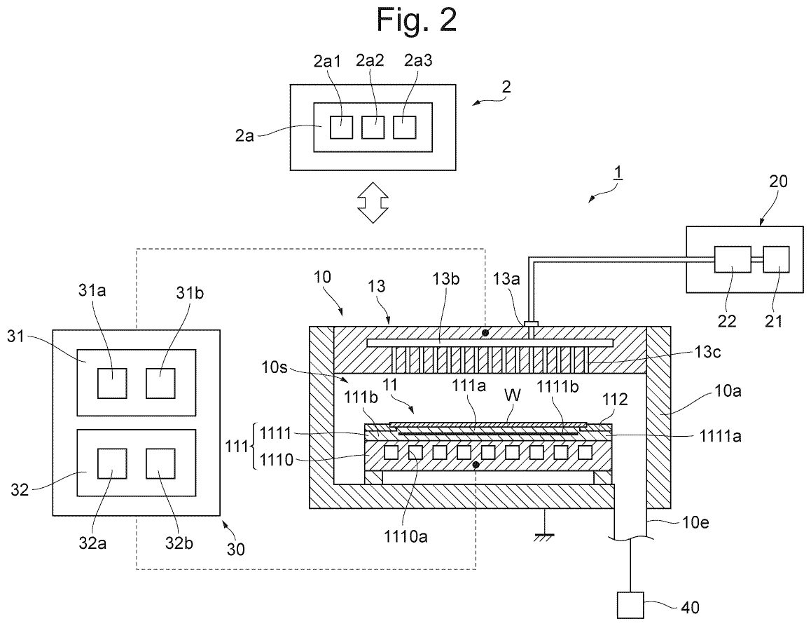

Hereinafter, a configuration example of the capacitively coupled plasma processing apparatus as an example of the plasma processing apparatus 1 will be described. FIG. 2 is a diagram for illustrating the configuration example of the capacitively coupled plasma processing apparatus.

The capacitively coupled plasma processing apparatus 1 includes the plasma processing chamber 10, the gas supply 20, a power supply system 30, and the exhaust system 40. In addition, the plasma processing apparatus 1 includes the substrate support 11 and a gas introduction unit. The gas introduction unit is configured to introduce at least one processing gas into the plasma processing chamber 10. The gas introduction unit includes a showerhead 13. The substrate support 11 is disposed in the plasma processing chamber 10. The showerhead 13 is disposed above the substrate support 11. In an embodiment, the showerhead 13 configures at least a part of a ceiling of the plasma processing chamber 10. The plasma processing chamber 10 has a plasma processing space 10s defined by the showerhead 13, a side wall 10a of the plasma processing chamber 10, and the substrate support 11. The plasma processing chamber 10 is grounded. The showerhead 13 and the substrate support 11 are electrically insulated from a housing of the plasma processing chamber 10.

The substrate support 11 includes a main body 111 and a ring assembly 112. The main body 111 has a center region 111a for supporting a substrate W and an annular region 111b for supporting the ring assembly 112. A wafer is an example of the substrate W. The annular region 111b of the main body 111 surrounds the center region 111a of the main body 111 in plan view. The substrate W is disposed on the center region 111a of the main body 111, and the ring assembly 112 is disposed on the annular region 111b of the main body 111 such that the ring assembly 112 surrounds the substrate W on the center region 111a of the main body 111. Therefore, the center region 111a is also referred to as a substrate support surface for supporting the substrate W, and the annular region 111b is also referred to as a ring support surface for supporting the ring assembly 112.

In an embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the center region 111a. In an embodiment, the ceramic member 1111a also has the annular region 111b. Another member that surrounds the electrostatic chuck 1111 may have the annular region 111b, such as an annular electrostatic chuck or an annular insulating member. In this case, the ring assembly 112 may be disposed on the annular electrostatic chuck or the annular insulating member, or may be disposed on both the electrostatic chuck 1111 and the annular insulating member. Further, at least one RF/DC electrode coupled to an RF power supply 31 and/or a DC power supply 32, which will be described later, may be disposed in the ceramic member 1111a. In this case, at least one RF/DC electrode functions as the lower electrode. In a case where a bias RF signal and/or a DC signal, which will be described later, are supplied to at least one RF/DC electrode, the RF/DC electrode is also referred to as a bias electrode. The conductive member of the base 1110 and at least one RF/DC electrode may function as lower electrodes.

The ring assembly 112 includes one or a plurality of annular members. In an embodiment, one or the plurality of annular members includes one or a plurality of edge rings and at least one cover ring. The edge ring is formed of a conductive material or an insulating material, and the cover ring is formed of an insulating material.

In addition, the substrate support 11 may include a temperature-controlled module configured to adjust at least one of the electrostatic chuck 1111, the ring assembly 112, and the substrate to a target temperature. The temperature-controlled module may include a heater, a heat transfer medium, a flow passage 1110a, or a combination thereof. A heat transfer fluid such as brine or a gas flows in the flow passage 1110a. In an embodiment, the flow passage 1110a is formed in the base 1110, and one or a plurality of heaters is disposed in the ceramic member 1111a of the electrostatic chuck 1111. Further, the substrate support 11 may include a heat transfer gas supply configured to supply the heat transfer gas to a gap between a back surface of the substrate W and the center region 111a.

The showerhead 13 is configured to introduce at least one processing gas from the gas supply 20 into the plasma processing space 10s. The showerhead 13 has at least one gas supply port 13a, at least one gas diffusion chamber 13b, and gas introduction ports 13c. The processing gas supplied to the gas supply port 13a passes through the gas diffusion chamber 13b and is introduced into the plasma processing space 10s from the gas introduction ports 13c. In addition, the showerhead 13 includes at least one upper electrode. In addition to the showerhead 13, the gas introduction unit may include one or a plurality of side gas injectors (SGI) attached to one or a plurality of opening portions formed on the side wall 10a.

The gas supply 20 may include at least one gas source 21 and at least one flow rate controller 22. In an embodiment, the gas supply 20 is configured to supply at least one processing gas to the showerhead 13 from each corresponding gas source 21 through each corresponding flow controller 22. Each flow controller 22 may include, for example, a mass flow controller or a pressure-controlled flow controller. Further, the gas supply 20 may include at least one flow modulation device that modulates or pulses a flow of at least one processing gas.

The power supply system 30 includes an RF power supply 31 that is coupled to the plasma processing chamber 10 via at least one impedance matching circuit. The RF power supply 31 is configured to supply at least one RF signal (RF power) to at least one lower electrode and/or at least one upper electrode. As a result, a plasma is formed from at least one processing gas supplied to the plasma processing space 10s. Therefore, the RF power supply 31 may function as at least a part of the plasma generator 12. Further, by supplying the bias RF signal to at least one lower electrode, a bias potential is generated in the substrate W, and an ion component in the formed plasma can be drawn into the substrate W.

In an embodiment, the RF power supply 31 includes a first RF generator 31a and a second RF generator 31b. The first RF generator 31a is coupled to at least one lower electrode and/or at least one upper electrode via at least one impedance matching circuit and is configured to generate a source RF signal (source RF power) for plasma formation. In an embodiment, the source RF signal has a frequency in the range of 10 MHz to 150 MHZ. In an embodiment, the first RF generator 31a may be configured to generate source RF signals having different frequencies. The generated one or plurality of source RF signals is supplied to at least one lower electrode and/or at least one upper electrode.

The second RF generator 31b is coupled to at least one lower electrode via at least one impedance matching circuit and is configured to generate the bias RF signal (bias RF power). The frequency of the bias RF signal may be the same as or different from the frequency of the source RF signal. In an embodiment, the bias RF signal has a frequency smaller than the frequency of the source RF signal. In an embodiment, the bias RF signal has a frequency in the range of 100 kHz to 60 MHz. In an embodiment, the second RF generator 31b may be configured to generate bias RF signals having different frequencies. The generated one or plurality of bias RF signals is supplied to at least one lower electrode. In addition, in various embodiments, at least one of the source RF signal and the bias RF signal may be pulsed.

In addition, the power supply system 30 may include a DC power supply 32 that is coupled to the plasma processing chamber 10. The DC power supply 32 includes a first DC generator 32a and a second DC generator 32b. In an embodiment, the first DC generator 32a is connected to at least one lower electrode, and is configured to generate the first DC signal. The generated first DC signal is applied to at least one lower electrode. In an embodiment, the second DC generator 32b is connected to at least one upper electrode and is configured to generate a second DC signal. The generated second DC signal is applied to at least one upper electrode.

In various embodiments, the first and second DC signals may be pulsed. In this case, a sequence of voltage pulses is applied to at least one lower electrode and/or at least one upper electrode. The voltage pulse may have a pulse waveform having a rectangular shape, a trapezoidal shape, a triangular shape, or a combination thereof. In an embodiment, a waveform generator for generating the sequence of voltage pulses from the DC signal is connected between the first DC generator 32a and at least one lower electrode. Therefore, the first DC generator 32a and the waveform generator configure the voltage pulse generator. In a case where the second DC generator 32b and the waveform generator configure the voltage pulse generator, the voltage pulse generator is connected to at least one upper electrode. The voltage pulse may have a positive polarity or a negative polarity. In addition, the sequence of voltage pulses may include one or a plurality of positive voltage pulses and one or a plurality of negative voltage pulses in one cycle. The first and second DC generators 32a and 32b may be provided in addition to the RF power supply 31, and the first DC generator 32a may be provided instead of the second RF generator 31b.

The exhaust system 40 may be connected to, for example, a gas exhaust port 10e provided at a bottom portion of the plasma processing chamber 10. The exhaust system 40 may include a pressure regulating valve and a vacuum pump. The pressure in the plasma processing space 10s is adjusted by the pressure regulating valve. The vacuum pump may include a turbo molecular pump, a dry pump, or a combination thereof.

### First Embodiment

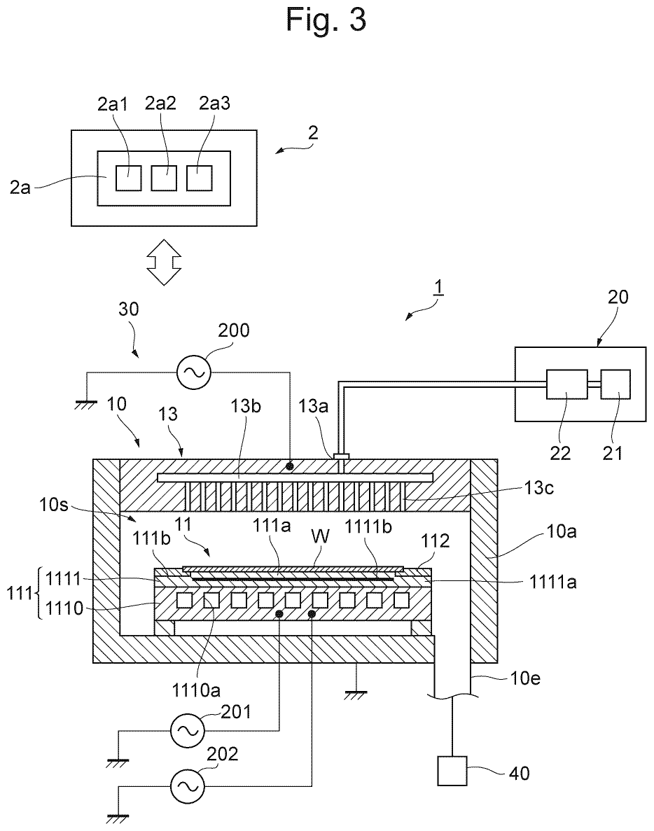

As illustrated in FIG. 3, the plasma processing apparatus 1 may have the power supply system 30 that supplies RF signals having three different RF frequencies to the upper electrode or the lower electrode. In an embodiment, the power supply system 30 may have a first RF power supply 200, a second RF power supply 201, and a third RF power supply 202. That is, the power supply system 30 is also referred to as an RF system.

In an embodiment, the first RF power supply 200 is electrically connected to the upper electrode and is configured to generate a first RF signal. The generated first RF signal is supplied to the upper electrode. The first RF power supply 200 may include a first RF generator. In an embodiment, the first RF signal has a frequency of a MHz band. In an embodiment, the first RF signal has a frequency in a range of 40 MHz to 150 MHz. In an embodiment, the first RF signal may have a frequency in a range of 80 MHz to 120 MHz.

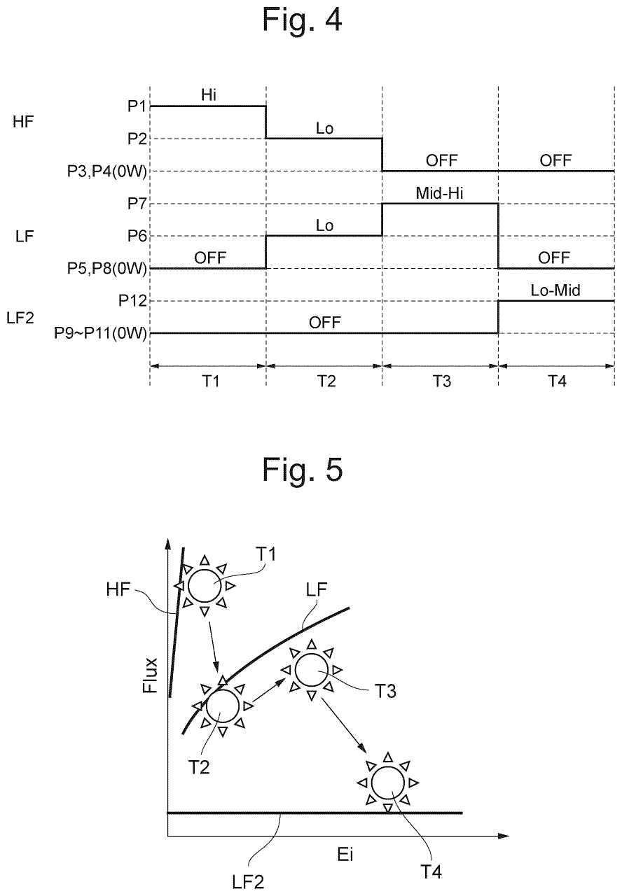

As illustrated in FIG. 4, during the plasma processing, cycles are executed at a repetition frequency of 0.1 kHz to 50 KHz, and each cycle has a first period T1, a second period T2, a third period T3, and a fourth period T4 in this order. In an embodiment, one cycle including the first period T1, the second period T2, the third period T3, and the fourth period T4 is set a plurality of times for the plasma processing of each substrate W. The second period T2, the third period T3, and the fourth period T4 may be shorter than the first period T1. Lengths of the second period T2, the third period T3, and the fourth period T4 may be the same as or different from each other. The fourth period T4 may be shorter than the second period T2 and the third period T3.

In an embodiment, the first RF signal (HF) has a first power level P1 in the first period T1 in each cycle, has a second power level P2 during the second period T2 in each cycle, has a third power level P3 during the third period T3 in each cycle, and has a fourth power level P4 during the fourth period T4 in each cycle. In an embodiment, the first power level P1 and the second power level P2 may be greater than the zero power level, and the first period T1 and the second period T2 may be in a state (ON state) in which the first RF signal (HF) is supplied to the upper electrode. The second power level P2 may be less than the first power level P1. In an embodiment, each of the third power level P3 and the fourth power level P4 is a zero power level, and the third period T3 and the fourth period T4 may be in a state in which the first RF signal (HF) is not supplied to the upper electrode (OFF state).

In an embodiment, as illustrated in FIG. 3, the second RF power supply 201 is electrically connected to the lower electrode and is configured to generate a second RF signal. The generated second RF signal is supplied to the lower electrode. The second RF power supply 201 may include a second RF generator. In an embodiment, the second RF signal has a frequency of a MHz band. In an embodiment, the second RF signal has a frequency less than the first RF signal (HF). In an embodiment, the second RF signal has a frequency in a range of 1 MHZ to 80 MHZ. In an embodiment, the second RF signal may have a frequency in a range of 10 MHz to 60 MHz.

In an embodiment, as illustrated in FIG. 4, The second RF signal (LF) has a fifth power level P5 during the first period T1 in each cycle, has a sixth power level P6 during the second period T2 in each cycle, has a seventh power level P7 during the third period T3 in each cycle, and has an eighth power level P8 during the fourth period T4 in each cycle. In an embodiment, the fifth power level P5 and the eighth power level P8 are the zero power level, and the first period T1 and the fourth period T4 may be in a state in which the second RF signal (LF) is not supplied to the lower electrode (OFF state). The sixth power level P6 and the seventh power level P7 are larger than the zero power level, and the second period T2 and the third period T3 may be in a state (ON state) in which the second RF signal (LF) is supplied to the lower electrode. The seventh power level P7 may be greater than the sixth power level P6.

In an embodiment, as illustrated in FIG. 3, the third RF power supply 202 is electrically connected to the lower electrode and is configured to generate a third RF signal. The generated third RF signal is supplied to the lower electrode. The third RF power supply 202 may include a third RF generator. In an embodiment, the third RF signal has a frequency less than the first RF signal (HF) and the second RF signal (LF). In an embodiment, the third RF signal has a frequency of a kHz band. In an embodiment, the third RF signal has a frequency in a range of 100 kHz to 1000 kHz. In an embodiment, the third RF signal may have a frequency in a range of 300 kHz to 600 kHz.

In an embodiment, as illustrated in FIG. 4, the third RF signal (LF2) has a ninth power level P9 during the first period T1 in each cycle, has a tenth power level P10 during the second period T2 in each cycle, has an eleventh power level P11 during the third period T3 in each cycle, and has a twelfth power level P12 during the fourth period T4 in each cycle. In an embodiment, the ninth power level P9, the tenth power level P10, and the eleventh voltage level P11 are the zero power level, and the first period T1, the second period T2, and the third period T3 may be in a state (OFF state) in which the third RF signal (LF2) is not supplied to the lower electrode. The twelfth power level P12 is greater than the zero power level, and the fourth period T4 may be a state (ON state) in which the third RF signal (LF2) is supplied to the lower electrode.

### Example of Plasma Processing

The plasma processing performed using the plasma processing apparatus 1 includes an etching process of etching a film on the substrate W using plasma. In an embodiment, the plasma processing is executed by the controller 2.

First, the substrate W is carried into the chamber 10 by a transport arm, is placed on the substrate support 11 by a lifter, and is held by suction on the substrate support 11 as illustrated in FIG. 3.

Next, the processing gas is supplied to the showerhead 13 by the gas supply 20, and is supplied from the showerhead 13 to the plasma processing space 10s. The processing gas supplied at this time includes a gas that generates an active species required for the etching process of the substrate W.

In an embodiment, the first RF signal (HF) is supplied to the upper electrode by the first RF power supply 200. The second RF signal (LF) and the third RF signal (LF2) are supplied to the lower electrode by the second RF power supply 201 and the third RF power supply 202. In this case, the atmosphere in the plasma processing space 10s is exhausted from the gas exhaust port 10e, and the inside of the plasma processing space 10s may be depressurized to a predetermined pressure. As a result, plasma is formed in the plasma processing space 10s, and the substrate W is subjected to the etching process.

In an embodiment, as illustrated in FIG. 4, during the first period T1 in the plasma processing, the first RF signal (HF) having the first power level P1 is supplied to the upper electrode (ON state). In an embodiment, the first power level P1 has a high power level (High). The second RF signal (LF) and the third RF signal (LF2) are not supplied to the lower electrode (OFF state).

FIG. 5 is a descriptive diagram for illustrating an example of a relationship between three types of RF signals and ion energy (Ei) and ion flux (Flux) of ions in plasma on the substrate W. The ion flux (Flux) correlates with the amount of ions generated in the plasma formed on the substrate W, and the ion energy (Ei) correlates with a force that draws ions into the substrate W (perpendicularity with respect to the surface of the substrate when ions enter the surface of the substrate). As illustrated in FIG. 5, the supply of the first RF signal (HF) having a high frequency contributes to a fluctuation of the ion flux (Flux) of ions in plasma. When the power level of the first RF signal (HF) is increased, the ion flux is increased. On the other hand, the ion energy (Ei) does not fluctuate much due to the supply of the first RF signal (HF). The supply of the second RF signal (LF) having a medium frequency contributes to both the fluctuation of the ion energy and the fluctuation of the ion flux. The supply of the third RF signal (LF2) having a low frequency contributes to the fluctuation of the ion energy. On the other hand, the supply of the third RF signal (LF2) does not substantially contribute to the fluctuation of the ion flux. By using a combination of three types of RF signals, the ion energy (Ei) and the ion flux (Flux) of plasma on the substrate W can be controlled.

During the first period T1 in an embodiment, only the first RF signal (HF) is supplied, and thus, on the substrate W in the plasma processing space 10s, the ion flux is high and the ion energy is low.

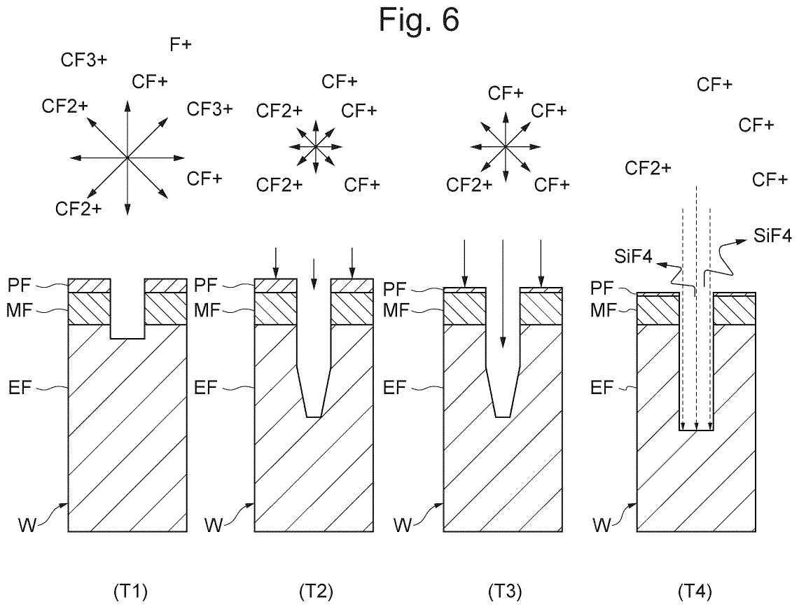

FIG. 6 is a descriptive diagram for illustrating an example of a behavior of ions in plasma during the first period T1, the second period T2, the third period T3, and the fourth period T4. As illustrated in FIG. 6, in an embodiment, during the first period T1, a large amount of ions or radicals generated from the CF-containing gas, which is the processing gas, are generated and diffuse, and a part of the ions or radicals are adsorbed on a mask film MF on the surface of the substrate W to form a protective film PF.

The example illustrated in FIG. 6 is an example in which a CF-containing gas is used as the processing gas, but the type of the processing gas is not particularly limited, and the processing gas may include, for example, at least one selected from the group consisting of a fluorine-containing gas, an oxygen-containing gas, and a halogen-containing gas. In addition, the example illustrated in FIG. 6 is an example in which a silicon oxide film is used as an etched film, but the type of the etched film or the mask film is not particularly limited, and the etched film or the mask film may include, for example, at least one selected from the group consisting of a silicon-containing film, a carbon-containing film, and a metal-containing film.

In an embodiment, during the second period T2 in the plasma processing, as illustrated in FIG. 4, the first RF signal (HF) having the second power level P2 is supplied to the upper electrode, and the second RF signal (LF) having the sixth power level P6 is supplied to the lower electrode (ON state). The third RF signal (LF2) is not supplied to the lower electrode (OFF state). In an embodiment, the second power level P2 has a power level less than the first power level P1 (Low). The sixth power level P6 has a power level less than the seventh power level P7 (Low).

In an embodiment, during the second period T2, as illustrated in FIG. 5, on the substrate W in the plasma processing space 10s, the ion flux is decreased and the ion energy is increased as compared with the first period T1. As a result, as illustrated in FIG. 6, during the second period T2, the generation of ions and radicals is suppressed as compared with the first period T1, and ions are drawn to a substrate W side. As a result, the etched film EF is etched while the protective film PF is formed on the surface of the substrate W. In an embodiment, the higher the second power level P2, the more the formation of the protective film RF is promoted, and the higher the sixth power level P6, the more the formation of the protective film RF and the etching of the etched film EF are promoted.

In an embodiment, during the third period T3 in the plasma processing, as illustrated in FIG. 4, the first RF signal (HF) is not supplied to the upper electrode (OFF state), the third RF signal (LF2) is not supplied to the lower electrode (OFF state), and the second RF signal (LF) having the seventh power level P7 is supplied to the lower electrode (ON state). In an embodiment, the seventh power level P7 has a power level greater than the sixth power level P6 (Middle-High).

In an embodiment, during the third period T3, as illustrated in FIG. 5, on the substrate W in the plasma processing space 10s, the ion flux is increased and the ion energy is also increased as compared with the second period T2. As a result, as illustrated in FIG. 6, during the third period T3, the generation of ions or radicals is promoted as compared with the second period T2, and the ions are drawn to the substrate W side as compared with the second period T2. As a result, the formation of the protective film RF and the etching of the etched film EF are promoted.

During the fourth period T4 in the plasma processing, as illustrated in FIG. 4, the first RF signal (HF) is not supplied to the upper electrode (OFF state), the second RF signal (LF) is not supplied to the lower electrode (OFF state), and the third RF signal (LF2) having the twelfth power level P12 is supplied to the lower electrode (ON state).

During the fourth period T4, as illustrated in FIG. 5, on the substrate W in the plasma processing space 10s, the ion flux is decreased and the ion energy is increased as compared with the third period T3. That is, a state in which the ion flux is low and the ion energy is high is obtained. As a result, as illustrated in FIG. 6, during the fourth period T4, the ions are strongly drawn to the substrate W side, and the etched film EF is etched. In this case, the ions are drawn perpendicularly to the substrate W, and the ions reach a bottom portion of a hole of the etched film EF, and a hole diameter of the bottom portion is secured. In addition, it is suppressed that a corner portion of the mask film MF is obliquely cut, and a side wall of the mask film MF or the etched film EF is swollen.

According to the present exemplary embodiment, the plasma processing apparatus 1 includes the first RF power supply 200 that supplies the first RF signal (HF) to the upper electrode, the second RF power supply 201 that supplies the second RF signal (LF) to the lower electrode, and the third RF power supply 202 that supplies the third RF signal (LF2) to the lower electrode. The first RF signal (HF) has the first power level P1 during the first period T1 in each cycle, has the second power level P2 less than the first power level P1 during the second period T2 in each cycle, has the third power level P3 during the third period T3 in each cycle, and has the fourth power level P4 of the zero power level during the fourth period T4 in each cycle. The second RF signal (LF) has the fifth power level P5 having the zero power level during the first period T1 in each cycle, has the sixth power level P6 during the second period T2 in each cycle, has the seventh power level P7 during the third period T3 in each cycle, and has the eighth power level P8 having the zero power level during the fourth period T4 in each cycle. The third RF signal (LF2) has the ninth power level P9 having the zero power level during the first period T1 in each cycle, has the tenth power level P10 having the zero power level during the second period T2 in each cycle, has the eleventh power level P11 having the zero power level during the third period T3 in each cycle, and the twelfth power level P12 during the fourth period T4 in each cycle. Accordingly, since the RF signals of three frequencies can be supplied at a predetermined power level in each of the periods T1 to T4 in each cycle, the ion energy and the ion flux of the generated plasma can be independently controlled, respectively. As a result, it is possible to improve the controllability of plasma formed on the substrate.

According to the present exemplary embodiment, during the first period T1 in each cycle, only the first RF signal (HF) having a high frequency is supplied, whereby it is possible to promote the formation of the protective film on the film on the substrate W while suppressing the etching of the film on the substrate W in a state in which the ion flux is high and the ion energy is low. During the second period T2 in each cycle, by supplying the first RF signal (HF) having a lower power level than the first period T1 and supplying the second RF signal (LF) having a medium frequency, thereby lowering the ion flux and increasing the ion energy, the formation of the protective film can be continued while suppressing the formation of the protective film on the substrate W, the ions can be drawn, and the etching of the film on the substrate W can be advanced. During the third period T3 in each cycle, by supplying the second RF signal (LF) having a higher power level than the second period T2, both the ion flux and the ion energy are increased, and the drawing of ions is further strengthened while a strong protective film is formed on the film on the substrate W, and the etching of the film on the substrate W can be promoted. As a result, the etching of the etched film can be advanced while suppressing the spread of the opening hole of the mask film. In addition, during the third period T3, the power levels of the first RF signal (HF) and the second RF signal (RF) are adjusted, and thus a balance between the action of formation of the protective film and the etching action by ions can be adjusted. During the fourth period T4 in each cycle, the third RF signal (LF2) having a low frequency is supplied, and thus the ions can be strongly drawn in a state in which the ion flux is low and the ion energy is high. As a result, the perpendicularity of the ions with respect to the substrate W can be increased, and the etching of the etched film can be promoted. As a result, it is suppressed that the diameter of the bottom portion of the hole formed in the etched film is decreased, a part of the width of the hole in the etched film is narrowed, and the corner portion of the mask film is obliquely cut. Therefore, an etching shape is improved.

### Other Examples of First Embodiment

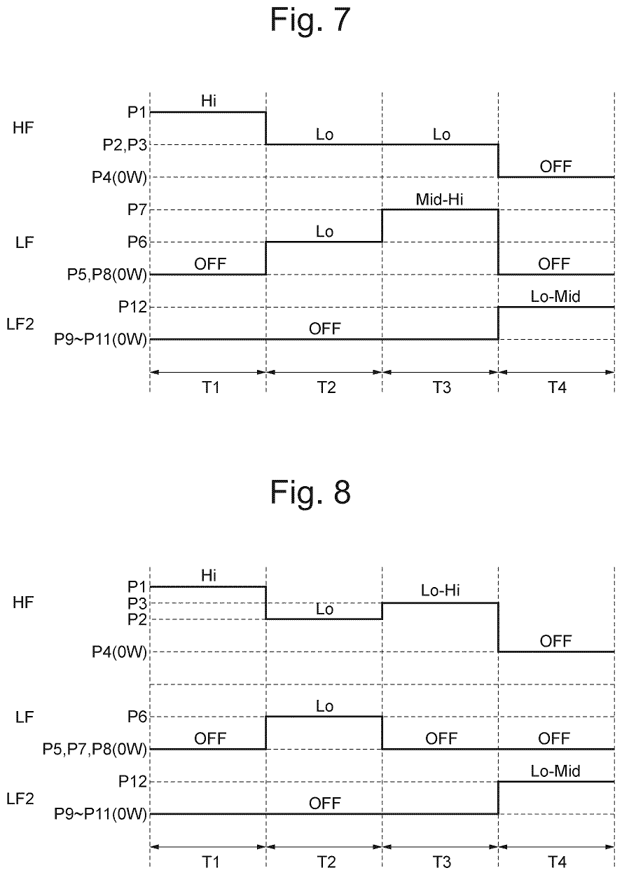

In the first embodiment, as illustrated in FIG. 7, during the third period T3 in each cycle, the third power level P3 of the first RF signal (HF) is equal to the second power level P2 (Low), and the seventh power level P7 of the second RF signal (LF) is greater than the sixth power level P6 (Low). In an embodiment, during the third period T3, the first RF signal (HF) is supplied to the upper electrode (ON state), and the second RF signal (LF) is supplied to the lower electrode (ON state). In an embodiment, during the third period T3, the ion flux of plasma on the substrate W is increased, and the ion energy is also increased as compared with the second period T2. Therefore, the action of forming the protective film by ions is improved, and the etching action is also improved.

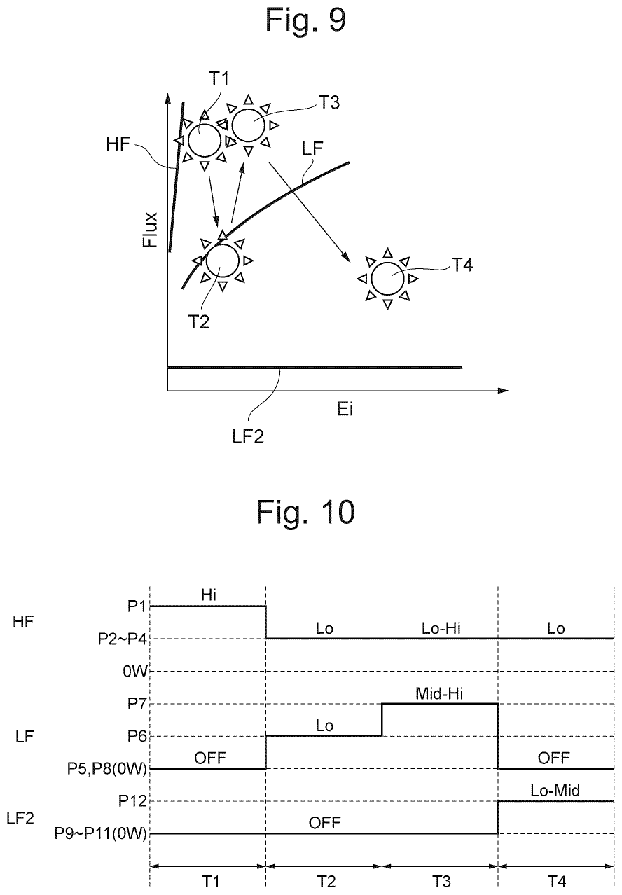

In the first embodiment, as illustrated in FIG. 8, during the third period T3 in each cycle, the third power level P3 of the first RF signal (HF) may be greater than the second power level P2 (Low), and the seventh power level P7 of the second RF signal (LF) may be the zero power level. In an embodiment, during the third period T3, the first RF signal (HF) is supplied to the upper electrode (ON state), and the second RF signal (LF) is not supplied to the lower electrode (OFF state). In an embodiment, as illustrated in FIG. 9, during the third period T3, the ion flux of plasma on the substrate is increased as compared with the second period T2, and thus the action of forming the protective film by ions is improved. The third power level P3 may be the same as the second power level P2.

In the first embodiment, as illustrated in FIG. 10, during the third period T3 in each cycle, the third power level P3 of the first RF signal (HF) may be the same as or greater than the second power level P2 (Low), and the seventh power level P7 of the second RF signal (LF) may be greater than the sixth power level P6 (Low). In an embodiment, during the third period T3, the first RF signal (HF) is supplied to the upper electrode (ON state), and the second RF signal (LF) is supplied to the lower electrode (OFF state). In an embodiment, during the third period T3, the ion flux of plasma on the substrate W is increased, and the ion energy is also increased as compared with the second period T2. Therefore, the action of forming the protective film by ions is improved, and the etching action is also improved. During the fourth period T4 in each cycle, the fourth power level P4 of the first RF signal (HF) may have a power level greater than the zero power level. In an embodiment, during the fourth period T4, the first RF signal (HF) may be supplied to the upper electrode (ON state). The fourth power level P4 may be the same as the third power level P3. In an embodiment, during the fourth period T4, the ion flux of plasma on the substrate W is increased as compared with the state in which the first RF signal (HF) is OFF, and thus the action of forming the protective film by ions is improved.

In the first embodiment, the first period T1, the second period T2, the third period T3, and the fourth period T4 in each cycle may be continuously performed, or a period (OFF period) in which all of the first RF signal (HF), the second RF signal (LF), and the third RF signal (LF2) are stopped may be provided between the first period T1 and the second period T2, between the second period T2 and the third period T3, and between the third period T3 and the fourth period T4. The first RF signal (HF) may be supplied to the lower electrode instead of the upper electrode.

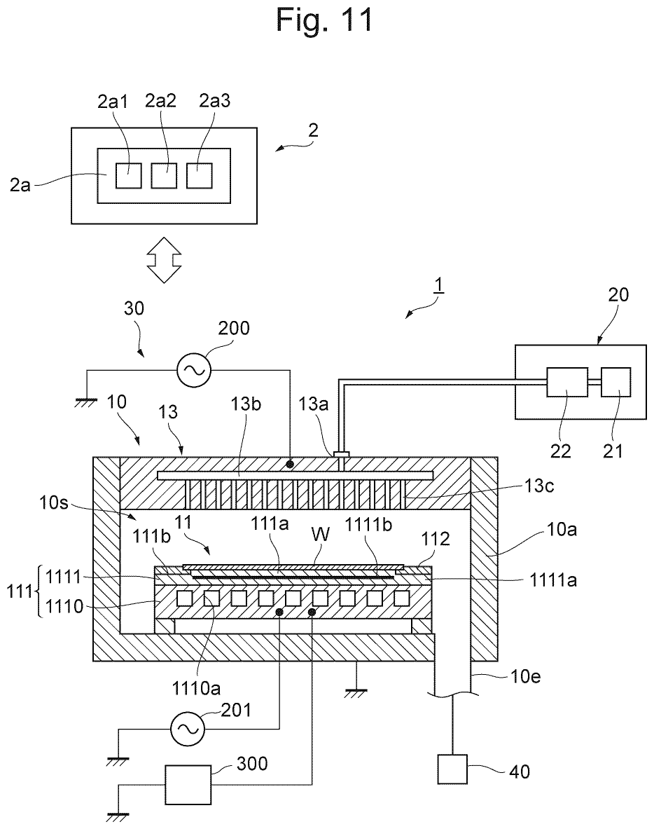

In the first embodiment, as illustrated in FIG. 11, the plasma processing apparatus 1 may have a voltage pulse generator 300 instead of the third RF power supply 202. That is, a voltage pulse signal may be applied to the lower electrode instead of the third RF signal (LF2). Other configurations of the plasma processing apparatus 1 may be the same as those of the above-described embodiment.

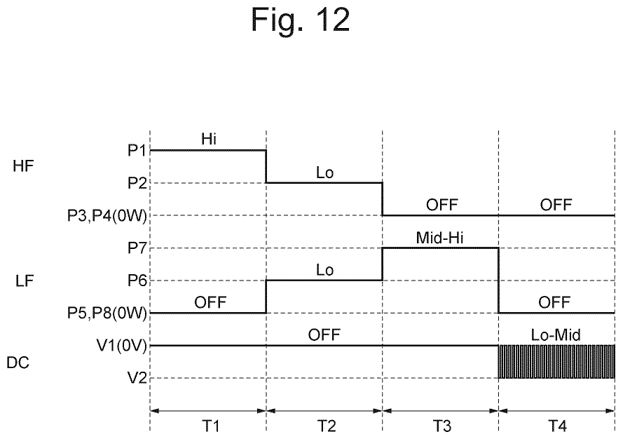

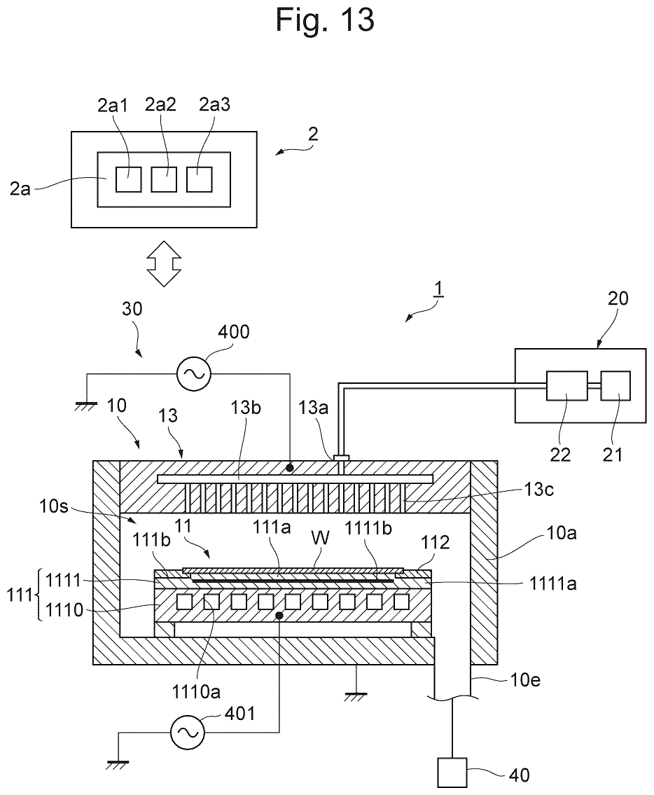

The voltage pulse generator 300 is configured to be electrically connected to the lower electrode and to generate the voltage pulse signal. The generated voltage pulse signal is applied to the lower electrode. As illustrated in FIG. 12, in an embodiment, a voltage pulse signal (DC) may have a first voltage level V1 during the first period T1, the second period T2, and the third period T3 in each cycle. The voltage pulse signal (DC) may have a sequence of voltage pulses having a second voltage level V2 during the fourth period T4 in each cycle.

In an embodiment, the first voltage level V1 has the zero voltage level. In an embodiment, the sequence of the voltage pulses has a pulse frequency in a range of 300 kHz to 600 kHz. An absolute value of the second voltage level V2 may be larger than an absolute value of the first voltage level V1. In an embodiment, the second voltage level V2 has a negative polarity. The supply and the power level of the first RF signal (HF) and the second RF signal (LF) may be the same as those in the first embodiment illustrated in FIG. 4.

During the fourth period T4 in an embodiment, since the voltage pulse signal (DC) is applied, the ion energy is increased on the substrate W in the plasma processing space 10s as compared with the first period T1, the second period T2, and the third period T3. As a result, during the fourth period T4, the ions are strongly drawn to the substrate W side, and the etched film EF is etched. In this case, the ions are drawn perpendicularly to the substrate W, and the ions reach a bottom portion of a hole of the etched film EF, and a hole diameter of the bottom portion is secured. In addition, it is suppressed that a corner portion of the mask film MF is obliquely cut, and a side wall of the mask film MF or the etched film EF is swollen. The present aspect in which the voltage pulse signal (DC) is applied by the voltage pulse generator 300 may be applied to all the first embodiment illustrated in FIGS. 7, 8, 10, and the like.

### Second Embodiment

As illustrated in FIG. 13, the plasma processing apparatus 1 may have the power supply system 30 that supplies the RF signal having the RF frequency of MHz band and the RF signal having RF frequency of kHz band to the upper electrode or the lower electrode. In an embodiment, the power supply system 30 may have a first RF power supply 400 and a second RF power supply 401.

In an embodiment, the first RF power supply 400 is electrically connected to the upper electrode and is configured to generate the first RF signal (RF signal of a MHz band). The generated first RF signal is supplied to the upper electrode. In an embodiment, the first RF signal has a frequency in a range of 40 MHz to 150 MHz. In an embodiment, the first RF signal may have a frequency in a range of 80 MHz to 120 MHz.

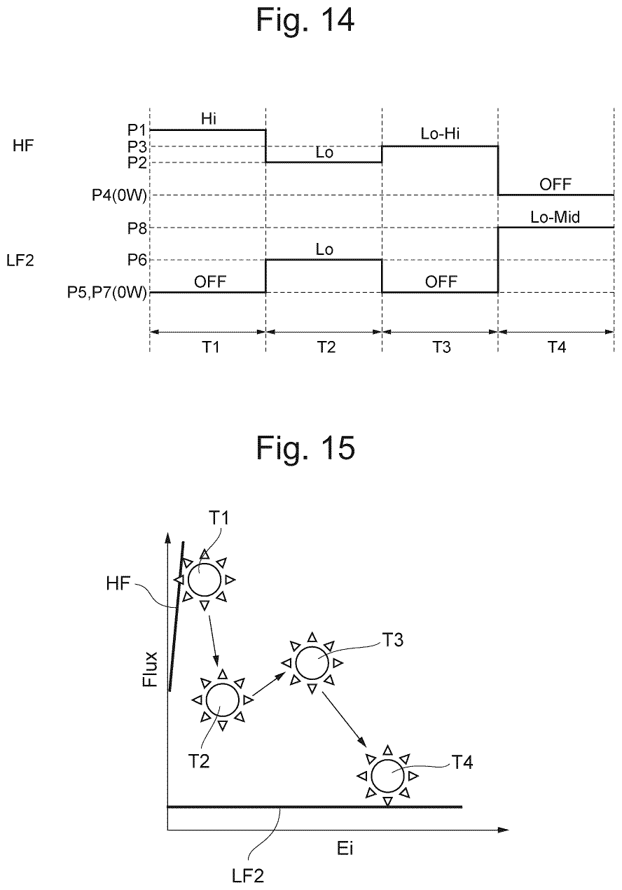

As illustrated in FIG. 14, during the plasma processing, cycles are executed at a repetition frequency of 0.1 kHz to 50 KHz, and each cycle has the first period T1, the second period T2, the third period T3, and the fourth period T4 in this order. In an embodiment, one cycle including the first period T1, the second period T2, the third period T3, and the fourth period T4 is set a plurality of times for the plasma processing of each substrate W. The second period T2, the third period T3, and the fourth period T4 may be shorter than the first period T1. Lengths of the second period T2, the third period T3, and the fourth period T4 may be the same as or different from each other. The fourth period T4 may be shorter than the second period T2 and the third period T3.

In an embodiment, the first RF signal (HF) has the first power level P1 during the first period T1 in each cycle, has the second power level P2 during the second period T2 in each cycle, has the third power level P3 during the third period T3 in each cycle, and has the fourth power level P4 during the fourth period T4 in each cycle. In an embodiment, the first power level P1 and the third power level P3 may be greater than the zero power level, and the first period T1 and the third period T3 may be in a state (ON state) in which the first RF signal (HF) is supplied to the upper electrode. The second power level P2 may be less than the first power level P1, and the third power level P3 may be greater than the second power level P2. In an embodiment, the fourth power level P4 may be the zero power level, and the fourth period T4 may be in a state (OFF state) in which the first RF signal (HF) is not supplied to the upper electrode. The third power level P3 may be the same as or less than the first power level P1.

In an embodiment, as illustrated in FIG. 13, the second RF power supply 401 is electrically connected to the lower electrode and is configured to generate the second RF signal (RF signal of kHz band). The generated second RF signal is supplied to the lower electrode. In an embodiment, the second RF signal has a frequency in a range of 100 KHz to 1000 kHz. In an embodiment, the second RF signal may have a frequency in a range of 300 kHz to 600 KHz.

In an embodiment, as illustrated in FIG. 14, the second RF signal (LF2) has the fifth power level P5 during the first period T1 in each cycle, has the sixth power level P6 in second period T2 in each cycle, has the seventh power level P7 during the third period T3 in each cycle, and has the eighth power level P8 during the fourth period T4 in each cycle. In an embodiment, the fifth power level P5 and the seventh power level may be the zero power level, and the first period T1 and the third period T3 may be in a state (OFF state) in which the second RF signal (LF2) is not supplied to the lower electrode. The sixth power level P6 may be greater than the zero power level and may be in a state (ON state) in which the second RF signal (LF2) is supplied to the lower electrode during the second period T2. In an embodiment, the eighth power level P8 may have a power level (Low-Middle) that is the same as or greater than the sixth power level P6 (Low), and may be in a state (ON state) in which the second RF signal (LF2) is supplied to the lower electrode during the fourth period T4.

FIG. 15 is a descriptive diagram for illustrating an example of a relationship between two types of RF signals and ion energy (Ei) and ion flux (Flux) of ions in plasma on the substrate W. As illustrated in FIG. 15, the supply of the first RF signal (HF) having the frequency of the MHz band contributes to the fluctuation of the ion flux (Flux) of ions in plasma. When the power level of the first RF signal (HF) is increased, the ion flux is increased. On the other hand, the ion energy (Ei) does not fluctuate much due to the supply of the first RF signal (HF). The supply of the second RF signal (LF2) having the frequency of the kHz band contributes to the fluctuation of the ion energy. On the other hand, the supply of the second RF signal (LF2) does not substantially contribute to the fluctuation of the ion flux. By using a combination of the RF signals having two types of frequencies of kHz and MHz, the ion energy (Ei) and the ion flux (Flux) on the substrate W can be controlled.

In an embodiment, during the first period T1 in the plasma processing, as illustrated in FIG. 14, the first RF signal (HF) having the first power level P1 is supplied to the upper electrode, and the second RF signal (LF2) is not supplied to the lower electrode (OFF state). That is, during the first period T1 in an embodiment, only the first RF signal (HF) is supplied, and thus, as illustrated in FIG. 15, the substrate W in the plasma processing space 10s is in a state in which the ion flux is high and the ion energy is low. As a result, during the first period T1, as in the aspect illustrated in FIG. 6, a large amount of ions and radicals generated from the processing gas are generated and diffused, and a part thereof is adsorbed on the mask film MF on the surface of the substrate W to form the protective film PF.

In an embodiment, during the second period T2 in the plasma processing, as illustrated in FIG. 14, the first RF signal (HF) having the second power level P2 is supplied to the upper electrode, and the second RF signal (LF2) having the sixth power level P6 is supplied to the lower electrode. The second power level P2 may be less than the first power level P1. During the second period T2 in an embodiment, as illustrated in FIG. 14, on the substrate W in the plasma processing space 10s, the ion flux is decreased, and the ion energy is increased as compared with the first period T1. As a result, during the second period T2, as in the aspect illustrated in FIG. 6, the generation of ions or radicals is suppressed as compared with the first period T1, and ions are drawn to the substrate W side. As a result, the etched film EF is etched while the protective film PF is formed on the surface of the substrate W. The higher the second power level P2, the more the formation of the protective film RF is promoted, and the higher the sixth power level P6, the more the formation of the protective film RF and the etching of the etched film EF are promoted.

In an embodiment, during the third period T3 in the plasma processing, as illustrated in FIG. 14, the first RF signal (HF) having the third power level P3 is supplied to the upper electrode, and the second RF signal (LF2) is not supplied to the lower electrode (OFF state). The third power level P3 may be greater than the second power level P2. During the third period T3 in an embodiment, as illustrated in FIG. 15, on the substrate W in the plasma processing space 10s, the ion flux is increased as compared with the second period T2. As a result, during the third period T3, as in the aspect illustrated in FIG. 6, the generation and diffusion of ions or radicals are promoted, and the protective film PF is formed.

In an embodiment, during the fourth period T4 in the plasma processing, as illustrated in FIG. 14, the first RF signal (HF) is not supplied to the upper electrode (OFF state), and the second RF signal (LF2) having the eighth power level P8 is supplied to the lower electrode. During the fourth period T4 in an embodiment, as illustrated in FIG. 15, on the substrate W in the plasma processing space 10s, the ion flux is decreased, and the ion energy is increased as compared with during the third period T3. As a result, during the fourth period T4, as in the aspect illustrated in FIG. 6, ions are strongly drawn to the substrate W side, and the etched film EF is etched. In this case, the ions are drawn perpendicularly to the substrate W, and the ions reach a bottom portion of a hole of the etched film EF, and a hole diameter of the bottom portion is secured. In addition, it is suppressed that a corner portion of the mask film MF is obliquely cut, and a side wall of the mask film MF or the etched film EF is swollen.

According to the present exemplary embodiment, the plasma processing apparatus 1 has the first RF power supply 400 that supplies the first RF signal (HF) having the RF frequency of MHz band to the upper electrode, and the second RF power supply 401 that supplies the second RF signal (LF2) having the RF frequency of kHz band to the lower electrode. The first RF signal (HF) has the first power level P1 during the first period T1 in each cycle, has the second power level P2 less than the first power level P1 during the second period T2 in each cycle, has the third power level P3 greater than the second power level P2 during the third period T3 in each cycle, and has the fourth power level P4 of the zero power level during the fourth period T4 in each cycle. The second RF signal (LF2) has the fifth power level P5 having the zero power level during the first period T1 in each cycle, has the sixth power level P6 during the second period T2 in each cycle, has the seventh power level P7 having the zero power level during the third period T3 in each cycle, and has the eighth power level P8 equal to or larger than the sixth power level P6 during the fourth period T4 in each cycle. Accordingly, in each of the periods T1 to T4 in each cycle, the RF signals having two frequencies of the MHz band and the kHz band can be supplied at a predetermined power level, and thus the ion energy and the ion flux of the generated plasma can be independently controlled, respectively. As a result, it is possible to improve the controllability of plasma formed on the substrate.

In the second embodiment, the second power level P2 and the sixth power level P6 may be the zero power level. In the second embodiment, the first period T1, the second period T2, the third period T3, and the fourth period T4 in each cycle may be continuously performed, or a period (OFF period) in which all of the first RF signal (HF) and the second RF signal (LF2) are stopped may be provided between the first period T1 and the second period T2, between the second period T2 and the third period T3, and between the third period T3 and the fourth period T4. The first RF signal (HF) may be supplied to the lower electrode instead of the upper electrode.

### Other Examples of Second Embodiment

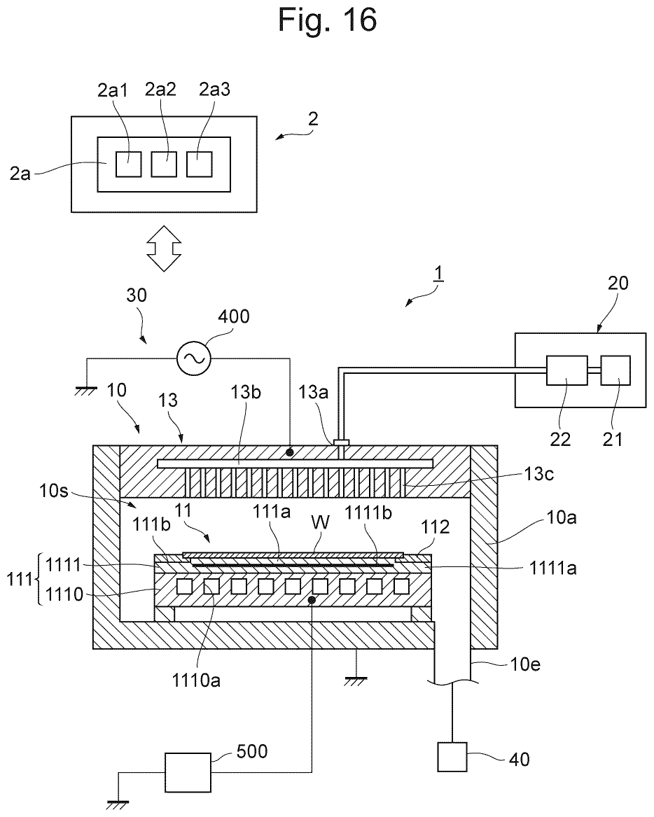

In the second embodiment, as illustrated in FIG. 16, the plasma processing apparatus 1 may have a voltage pulse generator 500 instead of the second RF power supply 401. That is, the voltage pulse signal may be applied to the lower electrode instead of the second RF signal (LF2). Other configurations of the plasma processing apparatus 1 may be the same as those of the above-described embodiment.

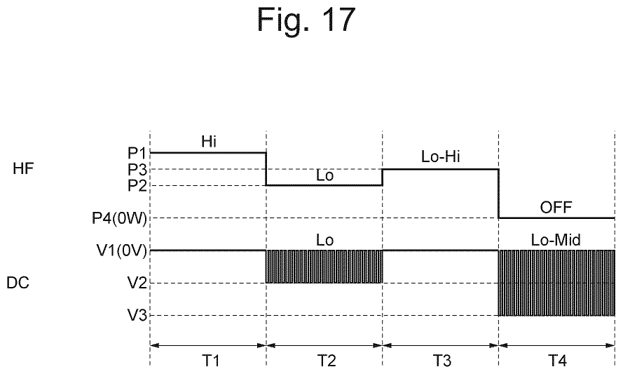

The voltage pulse generator 500 is electrically connected to the lower electrode and is configured to generate the voltage pulse signal. The generated voltage pulse signal is applied to the lower electrode. As illustrated in FIG. 17, in an embodiment, the voltage pulse signal (DC) has the first voltage level V1 during the first period T1 and the third period T3 in each cycle. The voltage pulse signal (DC) has a sequence of voltage pulses having the second voltage level V2 during the second period T2 in each cycle. The voltage pulse signal (DC) has a sequence of voltage pulses having the second voltage level V2 or the third voltage level V3 during the fourth period T4 in each cycle.

In an embodiment, the first voltage level V1 has the zero voltage level. In an embodiment, the sequence of the voltage pulses having the second voltage level V2 has a pulse frequency in a range of 300 kHz to 600 kHz. An absolute value of the second voltage level V2 may be larger than an absolute value of the first voltage level V1. In an embodiment, the sequence of the voltage pulses having the third voltage level V3 has a pulse frequency in a range of 300 kHz to 600 KHz. The absolute value of the third voltage level V3 may be larger than the absolute value of the second voltage level V2. In an embodiment, the second voltage level V2 and the third voltage level V3 have the negative polarity. The supply of the first RF signal (HF) and the power level may be the same as those in the second embodiment illustrated in FIG. 14.

During the second period T2 in an embodiment, since the voltage pulse signal (DC) having the second voltage level V2 is applied to the lower electrode, the ion energy is increased as compared with during the first period T1 on the substrate W in the plasma processing space 10s. As a result, during the second period T2, ions are drawn to the substrate W side. As a result, the protective film PF is formed, and the etched film EF is etched. In an embodiment, the higher the absolute value of the second voltage level V2, the more the etching of the etched film EF is promoted.

During the fourth period T4 in an embodiment, since the voltage pulse signal (DC) having the second voltage level V2 or the third voltage level V3 is applied to the lower electrode, the ion energy is increased as compared with the first period T1 and the third period T3 on the substrate W in the plasma processing space 10s. As a result, during the fourth period T4, the ions are strongly drawn to the substrate W side, and the etched film EF is etched. In this case, the ions are drawn perpendicularly to the substrate W, and the ions reach a bottom portion of a hole of the etched film EF, and a hole diameter of the bottom portion is secured. In addition, it is suppressed that a corner portion of the mask film MF is obliquely cut, and a side wall of the mask film MF or the etched film EF is swollen. In an embodiment, the larger the absolute value of the second voltage level V2 or the third voltage level V3, the more the etching of the etched film EF is promoted.

For example, in the embodiments described above, while the capacitively coupled plasma apparatus is illustratively described, the present disclosure is not limited thereto, and may be applied to other plasma apparatuses. For example, an inductively coupled plasma apparatus may be used instead of the capacitively coupled plasma apparatus. In this case, the inductively coupled plasma apparatus includes an antenna and a lower electrode. The lower electrode is disposed in the substrate support, and the antenna is disposed above the upper portion of or above the chamber. In an embodiment, the first RF power supply 200 is electrically connected to the antenna, and the second RF power supply 201 and the third RF power supply 202 are electrically connected to the lower electrode. The voltage pulse generator 300 may be applied instead of the third RF power supply 202. In addition, in an embodiment, the first RF power supply 400 is electrically connected to the antenna, and the second RF power supply 401 is electrically connected to the lower electrode. The voltage pulse generator 500 may be applied instead of the second RF power supply 401. In this way, the first RF power supplies 200 and 400 are electrically connected to the upper electrode of the capacitively coupled plasma apparatus or the antenna of the inductively coupled plasma apparatus. That is, the first RF power supplies 200 and 400 are coupled to the plasma processing chamber 10.

The embodiments of the present disclosure further include the following aspects.

### (Addendum 1)

A plasma processing apparatus including:
a chamber;
a substrate support disposed in the chamber and including a lower electrode; an upper electrode disposed above the substrate support;
a first RF power supply configured to supply a first RF signal to the upper electrode or the lower electrode, the first RF signal having a first RF frequency, the first RF signal having a first power level during a first period in each cycle, a second power level during a second period after the first period in each cycle, a third power level during a third period after the second period in each cycle, and a fourth power level during a fourth period after the third period in each cycle, the second power level being less than the first power level, and the fourth power level having a zero power level;
a second RF power supply configured to supply a second RF signal to the lower electrode, the second RF signal having a second RF frequency, the second RF signal having a fifth power level during the first period in each cycle, a sixth power level during the second period in each cycle, a seventh power level during the third period in each cycle, and an eighth power level during the fourth period in each cycle, and each of the fifth power level and the eighth power level having a zero power level; and
a third RF power supply configured to supply a third RF signal to the lower electrode, the third RF signal having a third RF frequency, the third RF signal having a ninth power level during the first period in each cycle, a tenth power level during the second period in each cycle, an eleventh power level during the third period in each cycle, and a twelfth power level during the fourth period in each cycle, and each of the ninth power level, the tenth power level and the eleventh power level having a zero power level.

### (Addendum 2)

The plasma processing apparatus according to Addendum 1, in which
the third power level has a zero power level, and
the seventh power level is greater than the sixth power level.

### (Addendum 3)

The plasma processing apparatus according to Addendum 1, in which
the third power level is equal to the second power level, and
the seventh power level is greater than the sixth power level.

### (Addendum 4)

The plasma processing apparatus according to Addendum 1, in which
the third power level is greater than the second power level, and
the seventh power level has a zero power level.

### (Addendum 5)

The plasma processing apparatus according to any one of Addenda 1 to 4, in which
the first RF frequency is larger than the second RF frequency, and
the second RF frequency is larger than the third RF frequency.

### (Addendum 6)

The plasma processing apparatus according to any one of Addenda 1 to 5, in which the third RF frequency is in a range of 300 kHz to 600 KHz.

### (Addendum 7)

A plasma processing apparatus including:
a chamber;
a substrate support disposed in the chamber and including a lower electrode;
an upper electrode disposed above the substrate support;
a first RF power supply configured to supply a first RF signal to the upper electrode or the lower electrode, the first RF signal having a first RF frequency, the first RF signal having a first power level during a first period in each cycle, a second power level during a second period after the first period in each cycle, a third power level during a third period after the second period in each cycle, and a fourth power level during a fourth period after the third period in each cycle, the second power level being less than the first power level, and the fourth power level having a zero power level;
a second RF power supply configured to supply a second RF signal to the lower electrode, the second RF signal having a second RF frequency, the second RF signal having a fifth power level during the first period in each cycle, a sixth power level during the second period in each cycle, a seventh power level during the third period in each cycle, and an eighth power level during the fourth period in each cycle, and each of the fifth power level and the eighth power level having a zero power level; and
a voltage pulse generator configured to apply a voltage pulse signal to the lower electrode, the voltage pulse signal having a first voltage level during the first period, the second period, and the third period in each cycle, and a sequence of voltage pulses having a second voltage level during the fourth period in each cycle, and an absolute value of the second voltage level being greater than an absolute value of the first voltage level.

### (Addendum 8)

The plasma processing apparatus according to Addendum 7, in which
the third power level has a zero power level, and
the seventh power level is greater than the sixth power level.

### (Addendum 9)

The plasma processing apparatus according to Addendum 7, in which
the third power level is equal to the second power level, and
the seventh power level is greater than the sixth power level.

### (Addendum 10)

The plasma processing apparatus according to Addendum 7, in which
the third power level is greater than the second power level, and
the seventh power level has a zero power level.

### (Addendum 11)

The plasma processing apparatus according to any one of Addenda 7 to 10, in which the second voltage level has a negative polarity.

### (Addendum 12)

The plasma processing apparatus according to any one of Addenda 7 to 11, in which the first voltage level has a zero voltage level.

### (Addendum 13)

The plasma processing apparatus according to any one of Addenda 7 to 12, in which the sequence of the voltage pulses has a pulse frequency in a range of 300 kHz to 600 kHz.

### (Addendum 14)

A plasma processing apparatus including:
a chamber;
a substrate support disposed in the chamber and including a lower electrode;
an upper electrode disposed above the substrate support;
a first RF power supply configured to supply a first RF signal having a first RF frequency to the upper electrode or the lower electrode, the first RF signal having a first RF frequency, the first RF frequency having a MHz band, the first RF signal having a first power level during a first period in each cycle, a second power level during a second period after the first period in each cycle, a third power level during a third period after the second period in each cycle, and a fourth power level during a fourth period after the third period in each cycle, the second power level being less than the first power level, the third power level being greater than the second power level, and the fourth power level having a zero power level; and
a second RF power supply configured to supply a second RF signal having a second RF frequency to the lower electrode, the second RF signal having a second RF frequency, the second RF frequency having a kHz band, the second RF signal having a fifth power level during the first period in each cycle, a sixth power level during the second period in each cycle, a seventh power level during the third period in each cycle, and an eighth power level during the fourth period in each cycle, each of the fifth power level and the seventh power level having a zero power level, and the eighth power level being equal to or greater than the sixth power level.

### (Addendum 15)

The plasma processing apparatus according to Addendum 14, in which the second RF signal has an RF frequency in a range of 300 kHz to 600 KHz.

### (Addendum 16)

A plasma processing apparatus including:
a chamber;
a substrate support disposed in the chamber and including a lower electrode;
an upper electrode disposed above the substrate support;
an RF power supply configured to supply an RF signal to the upper electrode or the lower electrode, the RF signal having a first power level during a first period in each cycle, a second power level during a second period after the first period in each cycle, a third power level during a third period after the second period in each cycle, and a fourth power level during a fourth period after the third period in each cycle, the second power level being less than the first power level, the third power level being greater than the second power level, and the fourth power level having a zero power level; and
a voltage pulse generator configured to apply a voltage pulse signal to the lower electrode, the voltage pulse signal having a first voltage level during the first period and the third period in each cycle, a sequence of voltage pulses having a second voltage level during the second period in each cycle, and a sequence of voltage pulses having the second voltage level or a third voltage level during the fourth period in each cycle, an absolute value of the second voltage level being greater than an absolute value of the first voltage level, and an absolute value of the third voltage level being greater than the absolute value of the second voltage level.

### (Addendum 17)

A power supply system for use in a plasma processing apparatus, including:
a first RF generator configured to generate a first RF signal having a first RF frequency, the first RF signal having a first power level during a first period in each cycle, a second power level during a second period after the first period in each cycle, a third power level during a third period after the second period in each cycle, and a fourth power level during a fourth period after the third period in each cycle, the second power level being less than the first power level, and the fourth power level having a zero power level;
a second RF generator configured to generate a second RF signal having a second RF frequency, the second RF signal having a fifth power level during the first period in each cycle, having a sixth power level during the second period in each cycle, a seventh power level during the third period in each cycle, and an eighth power level during the fourth period in each cycle, and each of the fifth power level and the eighth power level having a zero power level; and
a third RF generator configured to generate a third RF signal having a third RF frequency, the third RF signal having a ninth power level during the first period in each cycle, a tenth power level during the second period in each cycle, an eleventh power level during the third period in each cycle, and a twelfth power level during the fourth period in each cycle, and each of the ninth power level, the tenth power level and the eleventh power level having a zero power level.

### (Addendum 18)

A power supply system for use in a plasma processing apparatus, including:
a first RF generator configured to generate a first RF signal having a first RF frequency, the first RF signal having a first power level during a first period in each cycle, a second power level during a second period after the first period in each cycle, a third power level during a third period after the second period in each cycle, and a fourth power level during a fourth period after the third period in each cycle, the second power level being less than the first power level, and the fourth power level having a zero power level;
a second RF generator configured to generate a second RF signal having a second RF frequency, the second RF signal having a fifth power level during the first period in each cycle, a sixth power level during the second period in each cycle, a seventh power level during the third period in each cycle, and an eighth power level during the fourth period in each cycle, and each of the fifth power level and the eighth power level having a zero power level; and
a voltage pulse generator configured to generate a voltage pulse signal, the voltage pulse signal having a first voltage level during the first period, the second period, and the third period in each cycle, and a sequence of voltage pulses having a second voltage level during the fourth period in each cycle, and an absolute value of the second voltage level being greater than an absolute value of the first voltage level.

### (Addendum 19)

A power supply system for use in a plasma processing apparatus, including:
a first RF generator configured to generate a first RF signal having a first RF frequency, the first RF frequency having a MHz band, the first RF signal having a first power level during a first period in each cycle, a second power level during a second period after the first period in each cycle, a third power level during a third period after the second period in each cycle, and a fourth power level during a fourth period after the third period in each cycle, the second power level being less than the first power level, the third power level being greater than the second power level, and the fourth power level having a zero power level; and
a second RF generator configured to generate a second RF signal having a second RF frequency, the second RF frequency having a kHz band, the second RF signal having a fifth power level during the first period in each cycle, a sixth power level during the second period in each cycle, a seventh power level during the third period in each cycle, and an eighth power level during the fourth period in each cycle, each of the fifth power level and the seventh power level having a zero power level, and the eighth power level being equal to or greater than the sixth power level.

### (Addendum 20)

A power supply system for use in a plasma processing apparatus, including:
an RF generator configured to generate an RF signal, the RF signal having a first power level during a first period in each cycle, a second power level during a second period after the first period in each cycle, a third power level during a third period after the second period in each cycle, and a fourth power level during a fourth period after the third period in each cycle, the second power level being less than the first power level, the third power level being greater than the second power level, and the fourth power level having a zero power level; and
a voltage pulse generator configured to generate a voltage pulse signal, the voltage pulse signal having a first voltage level during the first period and the third period in each cycle, and a sequence of voltage pulses having a second voltage level during the second period in each cycle, and a sequence of voltage pulses having the second voltage level or a third voltage level during the fourth period in each cycle, an absolute value of the second voltage level being greater than an absolute value of the first voltage level, and an absolute value of the third voltage level being greater than the absolute value of the second voltage level.

Each of the above-described embodiments is described for the purpose of description, and is not intended to limit the scope of the present disclosure. Each of the above embodiments may be modified in various ways without departing from the scope and purpose of the present disclosure. For example, some configuration elements in one embodiment can be added to other embodiments. In addition, some configuration elements in one embodiment can be replaced with corresponding configuration elements in another embodiment.

According to one exemplary embodiment of the present disclosure, it is possible to provide a technique for improving the controllability of plasma formed on a substrate.

What is claimed is:

1. A plasma processing apparatus comprising:
a chamber;
a substrate support disposed in the chamber and including a lower electrode;
an upper electrode disposed above the substrate support;
a first RF power supply configured to supply a first RF signal to the upper electrode or the lower electrode, the first RF signal having a first RF frequency, the first RF signal having a first power level during a first period in each cycle, a second power level during a second period after the first period in each cycle, a third power level during a third period after the second period in each cycle, and a fourth power level during a fourth period after the third period in each cycle, the second power level being less than the first power level, and the fourth power level having a zero power level;
a second RF power supply configured to supply a second RF signal to the lower electrode, the second RF signal having a second RF frequency, the second RF signal having a fifth power level during the first period in each cycle, a sixth power level during the second period in each cycle, a seventh power level during the third period in each cycle, and an eighth power level during the fourth period in each cycle, each of the fifth power level and the eighth power level having a zero power level; and
a third RF power supply configured to supply a third RF signal to the lower electrode, the third RF signal having a third RF frequency, the third RF signal having a ninth power level during the first period in each cycle, a tenth power level during the second period in each cycle, an eleventh power level during the third period in each cycle, and a twelfth power level during the fourth period in each cycle, each of the ninth power level, the tenth power level and the eleventh power level having a zero power level.

2. The plasma processing apparatus according to claim 1, wherein
the third power level has a zero power level, and
the seventh power level is greater than the sixth power level.

3. The plasma processing apparatus according to claim 1, wherein
the third power level is equal to the second power level, and
the seventh power level is greater than the sixth power level.

4. The plasma processing apparatus according to claim 1, wherein
the third power level is greater than the second power level, and
the seventh power level has a zero power level.

5. The plasma processing apparatus according to claim 1, wherein
the first RF frequency is greater than the second RF frequency, and
the second RF frequency is greater than the third RF frequency.

6. The plasma processing apparatus according to claim 5, wherein the third RF frequency is in a range of 300 kHz to 600 KHz.

7. A plasma processing apparatus comprising:
a chamber;
a substrate support disposed in the chamber and including a lower electrode;
an upper electrode disposed above the substrate support;
a first RF power supply configured to supply a first RF signal to the upper electrode or the lower electrode, the first RF signal having a first RF frequency, the first RF signal having a first power level during a first period in each cycle, a second power level during a second period after the first period in each cycle, a third power level during a third period after the second period in each cycle, and a fourth power level during a fourth period after the third period in each cycle, the second power level being less than the first power level, and the fourth power level having a zero power level;
a second RF power supply configured to supply a second RF signal to the lower electrode, the second RF signal having a second RF frequency, the second RF signal having a fifth power level during the first period in each cycle, a sixth power level during the second period in each cycle, a seventh power level during the third period in each cycle, and an eighth power level during the fourth period in each cycle, each of the fifth power level and the eighth power level having a zero power level; and
a voltage pulse generator configured to apply a voltage pulse signal to the lower electrode, the voltage pulse signal having a first voltage level during the first period, the second period and the third period in each cycle, and a sequence of voltage pulses having a second voltage level during the fourth period in each cycle, an absolute value of the second voltage level being greater than an absolute value of the first voltage level.

8. The plasma processing apparatus according to claim 7, wherein
the third power level has a zero power level, and
the seventh power level is greater than the sixth power level.

9. The plasma processing apparatus according to claim 7, wherein
the third power level is equal to the second power level, and
the seventh power level is greater than the sixth power level.

10. The plasma processing apparatus according to claim 7, wherein
the third power level is greater than the second power level, and
the seventh power level has a zero power level.

11. The plasma processing apparatus according to claim 7, wherein the second voltage level has a negative polarity.

12. The plasma processing apparatus according to claim 11, wherein the first voltage level has a zero voltage level.

13. The plasma processing apparatus according to claim 7, wherein the sequence of the voltage pulses has a pulse frequency in a range of 300 kHz to 600 KHz.

14. A plasma processing apparatus comprising:
a chamber;
a substrate support disposed in the chamber and including a lower electrode;
an upper electrode disposed above the substrate support;
a first RF power supply configured to supply a first RF signal having a first RF frequency to the upper electrode or the lower electrode, the first RF signal having a first RF frequency, the first RF frequency having a MHz band, the first RF signal having a first power level during a first period in each cycle, a second power level during a second period after the first period in each cycle, a third power level during a third period after the second period in each cycle, and a fourth power level during a fourth period after the third period in each cycle, the second power level being less than the first power level, the third power level being greater than the second power level, and the fourth power level having a zero power level; and
a second RF power supply configured to supply a second RF signal having a second RF frequency to the lower electrode, the second RF signal having a second RF frequency, the second RF frequency having a kHz band, the second RF signal having a fifth power level during the first period in each cycle, a sixth power level during the second period in each cycle, a seventh power level during the third period in each cycle, and an eighth power level during the fourth period in each cycle, each of the fifth power level and the seventh power level having a zero power level, and the eighth power level being equal to or greater than the sixth power level.

15. The plasma processing apparatus according to claim 14, wherein the second RF signal has an RF frequency in a range of 300 kHz to 600 KHz.
